(19) United States
(12) Patent Application Publication
(10) Pub. No.: US 2023/0366931 A1
(43) Pub. Date: Nov. 16, 2023

(54) SECURE JOINT TEST ACTION GROUP (JTAG)

(71) Applicant: BAE Systems Information and Electronic Systems Integration Inc., Nashua, NH (US)

(72) Inventors: Daniel L. Stanley, Warrenton, VA (US); David D. Moser, Haymarket, VA (US); Joshua C. Schabel, Apex, NC (US); Michael J. Bear, Falls Church, VA (US); Sheldon L. Grass, Chester, NH (US); Tate J. Keegan, Merrimack, NH (US)

(73) Assignee: BAE Systems Information and Electronic Systems Integration Inc., Nashua, NH (US)

(21) Appl. No.: 17/742,034

(22) Filed: May 11, 2022

(51) Int. Cl. G01R 31/3185

(52) U.S. Cl. CPC G01R 31/318597

(57) ABSTRACT

A port protection network provided with a joint test action group (JTAG) core and method of use. The port protection network includes an agent device operatively connected with a streaming bus and a test access port (TAP) of the JTAG core. The port protection network also includes a master device operatively connected with the streaming bus and the TAP of the JTAG core. In the port protection network, the agent device is configured to selectively restrict access to the master device through the JTAG core.

### TECHNICAL FIELD

The present disclosure generally relates to a joint test action group (hereinafter “JTAG”). More particularly, the present disclosure generally relates to securing at least one JTAG in a semiconductor integrated circuit. Specifically, the present disclosure relates to securing at least one JTAG in a semiconductor integrated circuit with a port protection network creating a two-step access protocol.

### BACKGROUND

In semiconductor integrated circuits, design-for-testing or design-for-testability platforms (“DFT”) provide arrangements of electrical components for testing specific operations and applications. In these platforms, at least one JTAG core may be provided with these types of integrated circuits for testing interconnects on printed circuit boards (PCBs) that are implemented at the integrated circuit level without using physical test probes. As such, these JTAG cores are configured to provide debugging operations and features such as JTAG boundary testing, full on-chip buss memory mapping, memory built-in self-testing (MBIST), logic built-in self-testing (LBIST), and other various debugging operations of the like. The use of these JTAG cores are becoming more essential and helpful as integrated circuits become more complex. However, the functionality of the JTAG cores also create detrimental issues for designers and users of these JTAGs inside of integrated circuits. Specifically, these JTAG cores created unwanted and unauthorized access into the integrated circuits through these JTAG cores when these JTAG cores are provided in integrated circuits outside of the testing environment.

To combat these issues, conventional JTAG cores are configured with a security and/or access parameter that enables these JTAG cores to restrict unauthorized use. As such, an access key may be loaded into a test access port controller (TAP) of a JTAG core to provide access into the JTAG core and to downstream device in communication with the JTAG core. Generally, these access keys are rather simple keys that prevent and/or restrict simple attacks by unauthorized users. However, unauthorized users may bombard the JTAG core with various commands to uncover and/or retrieved these conventional access keys. More so, these conventional access keys for JTAG cores are well known in the art, which allows for numerous strategies and attacks in acquiring these access keys for the specific JTAG core.

### SUMMARY

The presently disclosed port protection network for at least one JTAG core provides an additional level of security and access into the at least one JTAG via field-programmable gate array (FPGA) programmed logic. The port protection network provides an agent-master protocol that is configured to be selectively restrictive to users for enabling operation of the at least one JTAG core in addition to the access key. The agent-master protocol is also configured with a security and/or protection parameter in an agent device to enable access into a streaming bus or on-chip bus operatively connected with the at least one JTAG core. As such the port protection network for a JTAG core disclosed herein addresses some of the inadequacies of previously known JTAG core security protocol.

In one aspect, an exemplary embodiment of the present disclosure may provide an integrated circuit. The integrated circuit includes a streaming bus. The integrated circuit also includes at least one joint test action group (JTAG) core operatively connected with the streaming bus. The at least one JTAG core comprises a test access port (TAP) adapted to connect with a JTAG interface, wherein the at least one JTAG core is adapted to access a plurality of programmable devices. The at least one JTAG core also comprises a port protection network and a set of preconfigured security parameters. Each of the port protection network and the at least one JTAG interface are configured to selectively restrict access, via the at least one JTAG core, to the plurality of programmable devices.

This exemplary embodiment or another exemplary embodiment may further include that wherein each of the port protection network and the at least one JTAG interface is configured to selectively restrict access to the plurality of programmable devices through the at least one JTAG core independently and separately from one another. This exemplary embodiment or another exemplary embodiment may further include that the port protection network comprises an agent device operatively connected with the streaming bus and the TAP; wherein the agent device is operative to communicate with one or both of the streaming bus and the TAP. This exemplary embodiment or another exemplary embodiment may further include that the port protection network further comprises: a master device operatively connected with the streaming bus and the TAP; wherein the master device is operative to communicate with one or all of the agent device, the TAP, and the streaming bus. This exemplary embodiment or another exemplary embodiment may further include that the set of preconfigured security parameters further comprises: a first protection parameter provided with the agent device of the port protection network that maintains the agent device in a locked state; and a second protection parameter provided with the at least one JTAG core that maintains the at least one JTAG core in a locked state. This exemplary embodiment or another exemplary embodiment may further include a first security channel of the port protection network operatively connecting the agent device and the TAP with one another; wherein the agent device of the port protection network, in response to receiving a first security key matching the first protection parameter, is in an unlocked state once the first security key is loaded into the TAP of the at least one JTAG and output to the agent device via the first security channel. This exemplary embodiment or another exemplary embodiment may further include that the port protection network further comprises: a second security channel operatively connecting the master device and the TAP with one another; wherein the agent device and the master device communicate with one another via the first security channel and the second security channel; and wherein the master device is accessible subsequent to the agent device of the port protection network being provided in the unlocked state. This exemplary embodiment or another exemplary embodiment may further include that wherein the at least one JTAG core, in response to receiving a second security key matching the second protection parameter, is in an unlocked state once the second security key is loaded into the TAP of the at least one JTAG core. This exemplary embodiment or another exemplary embodiment may further include that the port protection network further comprises a first side channel operatively connecting the agent device and the streaming bus with one another; wherein the streaming bus outputs data to the agent device via the first side channel. This exemplary embodiment or another exemplary embodiment may further include that the port protection network further comprises: a second side channel operatively connects the master device and the streaming bus with one another; wherein the master device outputs data to the streaming device via the second side channel.

In another aspect, an exemplary embodiment of the present disclosure may provide a port protection network provided with a joint test action group (JTAG) core. The port protection network includes an agent device operatively connected with a streaming bus and a test access port (TAP) of the JTAG core. The port protection network also includes a master device operatively connected with the streaming bus and the TAP of the JTAG core. The agent device is configured to selectively restrict access to the master device through the JTAG core.

This exemplary embodiment or another exemplary embodiment may further include a set of preconfigured security parameters provided with the port protection network and the JTAG core, the set of preconfigured security parameters comprising: a first protection parameter provided with the agent device of the port protection network that maintains the agent device in a locked state; and a second protection parameter provided with the at least one JTAG core that maintains the at least one JTAG core in a locked state. This exemplary embodiment or another exemplary embodiment may further include a first security channel of the port protection network operatively connecting the agent device and the TAP with one another; wherein the agent device, in response to receiving a first security key matching the first protection parameter, is in an unlocked state once the first security key is loaded into the TAP of the JTAG core and output to the agent device via the first security channel. This exemplary embodiment or another exemplary embodiment may further include that the port protection network further comprises: a second security channel operatively connecting the master device and the TAP with one another; wherein the agent device and the master device communicate with one another via the first security channel and the second security channel; and wherein the master device is accessible once the agent device is unlocked. This exemplary embodiment or another exemplary embodiment may further include that the JTAG core, in response to receiving a second security key matching the second protection parameter, is in an unlocked state once the second security key is loaded into the TAP of the JTAG core.

In yet another aspect, an exemplary embodiment of the present disclosure may provide a method of accessing a plurality of programmable devices of an application-specific integrated circuit (ASIC). The method comprises steps of: loading a first security key into a test access port (TAP) of at least one joint test action group (JTAG) core having a port protection network; loading a second security key into the TAP of the at least one JTAG core; outputting the first security key, via the TAP, to an agent device of the port protection network; unlocking the agent device, via the first security key, from a locked state to an unlocked state; activating a master device of the port protection network, via the agent device, from a deactivated state to an activated state; and accessing the plurality of programmable devices of the ASIC.

This exemplary embodiment or another exemplary embodiment further includes a step of outputting data, via a first side channel, from the master device to a streaming bus of the ASIC. This exemplary embodiment or another exemplary embodiment further includes a step of outputting the data, via the streaming bus, to at least one of the plurality programmable devices of the ASIC. This exemplary embodiment or another exemplary embodiment further includes a step of communicating, via a second side channel, between the agent device and the streaming bus. This exemplary embodiment or another exemplary embodiment further include that the step of outputting the first security key, via the TAP, to the agent device of the port protection network further includes that the first security key is outputted over a first security channel of the port protection network operatively connecting the agent device and the TAP to one another.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1 is a PRIOR ART IC with a conventional JTAG core

FIG. 2 is an integrated circuit with a JTAG core having a port protection network in accordance with an aspect the present disclosure.

FIG. 3 is the integrated circuit with a JTAG core having the port protection network in accordance with an aspect the present disclosure.

FIG. 4 is a flowchart for a method of accessing a plurality of programmable devices of an application-specific integrated circuit (ASIC)

Similar numbers refer to similar parts throughout the drawings.

### DETAILED DESCRIPTION

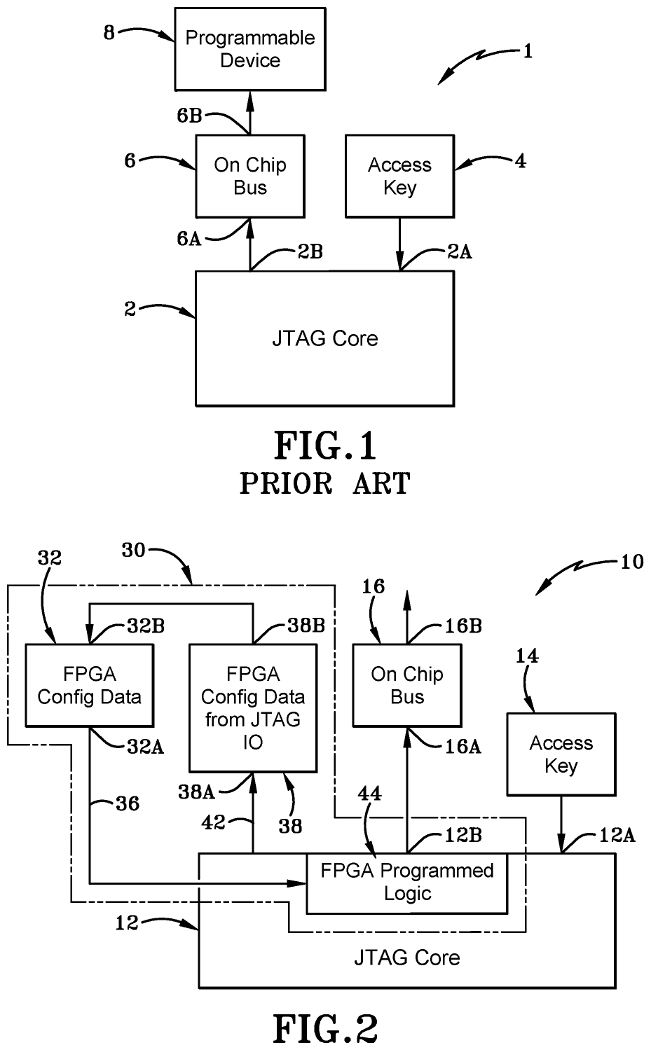

FIG. 1 illustrates a PRIOR ART integrated circuit (hereinafter “IC”) platform generally referred to as 1. The PRIOR ART IC 1 includes conventional integrated circuit techniques that add testing features to hardware operatively connected with the PRIOR ART IC 1. The PRIOR ART IC 1 may include any hardware or components considered suitable to be used with the PRIOR ART IC 1 during operation. In this instance, the PRIOR ART IC 1 may be provided on a design-for-testing (DFT) platform for testing and debugging operations. In other exemplary embodiments, PRIOR ART IC 1 may be provided on platforms for specific, industrial operations outside of testing and debugging operations.

As provided herein, the PRIOR ART IC 1 includes at least one joint test action group (hereinafter “JTAG”) core 2. The at least one JTAG core 2 is a conventional, preexisting JTAG core that enables users of these PRIOR ART ICs to test interconnects in the PRIOR ART IC 1 that are implemented at the integrated circuit level. Generally, the JTAG core 2 is configured to provide debugging operations and features such as JTAG boundary testing, full on-chip buss memory mapping, memory built-in self-testing (MBIST), logic built-in self-testing (LBIST), and other various debugging operations of the like.

The at least one JTAG core 2 includes an input port 2A that allows users access into the at least one JTAG core 2 for loading data and/or information into the at least one JTAG core 2. The at least one JTAG core 2 also includes an output port 2B that allows the user to communicate with other programmable devices and components operatively connected with the PRIOR ART IC 1, which is described in more detail below.

The at least one JTAG core 2 is provided with a predefined access parameter and/or lock that allows selective access and/or restriction into the JTAG core 2. Generally, this predefined access parameter prevents unauthorized users from accessing the at least one JTAG core 2 at the input port 2A without knowledge of the predefined access parameter. To access the at least one JTAG core 2, an access key 4 may be loaded into the at least one JTAG core 2 via the input port 2A. If the access key 4 matches the predefined access parameter, the at least one JTAG core 2 will allow access to the user. If the access key 4 fails to match the predefined access parameter, the at least one JTAG core 2 will deny access to the user. As such, the combination of the predefined access parameter of the at least one JTAG core 2 and the access key 4 provides a protection parameter to prevent unauthorized access into the JTAG core 2, which also prevents any communication and/or modification to downstream programmable devices in communication with the at least one JTAG core 2.

The PRIOR ART IC 1 also includes a streaming bus or on-bus chip 6. The streaming bus 6 includes at least one input port 6A and at least one output port 6B. As provided herein, the streaming bus 6 operatively connects with the at least one JTAG core 2. Specifically, the at least one input port 6A of the streaming bus operatively connects with the output port 2B of the at least on JTAG core 2. While not illustrated herein, the streaming bus 6 operatively connects with at least one programmable device 8. Specifically, the at least one output port 6B of the streaming bus operatively connects with an input port of the at least one programmable device.

Conventionally, the PRIOR ART IC 1 only operates once the access key 4 is loaded into the at least one JTAG core 2 to allow access into the one JTAG core 2 and downstream devices. Once access is granted, the user has full range of communication with downstream devices operatively connected with the streaming bus 6 in the PRIOR ART IC 1. With this access, the user may be enabled to modify and manipulate downstream programmable devices that are in communication with the streaming bus 6.

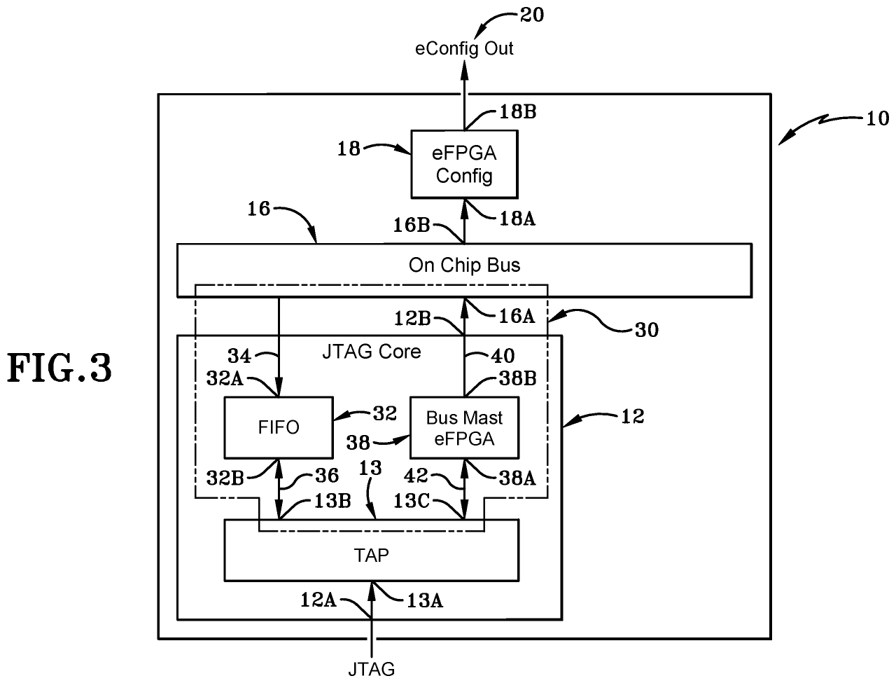

As illustrated in FIGS. 2 and 3, an IC 10 is provided in accordance with one aspect of the present disclosure. The IC 10 may include suitable integrated circuit techniques that add testing features to hardware operatively connected with the IC 10. The IC 10 may also include any hardware or components considered suitable to be used with the IC 10 during operation. The IC 10 may also be operatively connected with other suitable integrated circuits for specific uses and/or operations (e.g., application-specific integrated circuits (ASICs), field-programmable gate arrays (FPGAs), and other integrated circuits of the like). In this instance, the IC 10 may be provided on a design-for-testing (DFT) platform for testing and debugging operations. In another instance, the IC 10 may be restricted from testing and debugging operations and be used for limited operations, which is described in more detail below.

Referring to FIGS. 2 and 3, the IC 10 includes at least one JTAG core 12. The at least one JTAG core 12 may be a preexisting JTAG core that enables users of the IC 10 to test interconnects in the IC 10 that are implemented at the integrated circuit level. The at least one JTAG core 12 includes at least one input port 12A that allows users access into the at least one JTAG core 12 for loading data and/or information into the at least one JTAG core 12. The at least one JTAG core 12 also includes at least one output port 12B (see FIG. 3) that allows the user to communicate with other programmable devices and components operatively connected with the IC 10, which is described in more detail below.

Referring to FIG. 3, a test access port controller (hereinafter “TAP”) 13 is provided with the at least one JTAG core 12. The TAP 13 is enabled for executing tests and managing data flow along boundary cells of the IC 10. The TAP 13 includes a first input/output (I/O) port 13A, a second I/O port 13B, and a third I/O port 13C. As illustrated herein, the first I/O port 13A operatively connects with the input port 12A of the at least one JTAG core 12 for allowing access into the at least one JTAG core 12. The second and third I/O ports 13B, 13C of the TAP 13 are discussed in more detail below. In other exemplary embodiments, the TAP 13 may include any suitable number of I/O ports for a specific use and/or purpose for operatively connecting with other devices in the JTAG core 12.

The at least one JTAG core 12 is provided with a predefined access parameter and/or lock that allows selective access and/or restriction into the JTAG core 12. Generally, this predefined access parameter prevents unauthorized users from accessing the at least one JTAG core 12 without knowledge of the predefined access parameter. To access the at least one JTAG core 12, an access key 14 is loaded into the first I/O port 13A of the TAP 13. If the access key 14 matches the predefined access parameter, the TAP 13 allows access into the at least one JTAG CORE 12. If the access key 14 fails to match the predefined access parameter, the TAP 13 denies access into the at least one JTAG CORE 12. As such, the combination of the predefined access parameter of the at least one JTAG core 12 and the access key 14 provides a protection parameter to prevent unauthorized access into the JTAG core 12, which also prevents any communication and/or modification to downstream programmable devices in communication with the at least one JTAG core 12.

The IC 10 also includes a streaming bus or on-bus chip 16. The streaming bus 16 includes at least one input port 16A and at least one output port 16B. As provided herein, the streaming bus 16 operatively connects with the at least one JTAG core 12. Specifically, the at least one input port 16A of the streaming bus operatively connects with the output port 12B of the at least on JTAG core 12.

Referring to FIG. 3, the streaming bus 16 operatively connects with an embedded field programmable gate array configuration controller (eFPGA) 18 provided in the IC 10. As provided herein, the eFPGA 18 may have an intellectual property (IP) architecture preconfigured for any desired operations and/or applications. The eFPGA 18 includes at least one input port 18A that operatively connects with the at least one output port 16B of the streaming bus 16. Additionally, the eFPGA 18 also includes at least one output 18B that operatively connects with at least one programmable device 20. Once access is granted by the at least one JTAG core 12, users have access to the eFPGA 18 along with the at least one programmable device 20 operatively connected with the eFPGA 18.

Referring to FIGS. 2 and 3, the at least one JTAG core 12 includes a port protection network 30 operatively connected with the TAP 13 and the streaming bus 16, which is described in more detail below. The port protection network 30 is configured to selectively restrict access into the JTAG core 12 in addition to the access system between the predefined parameters of the at least one JTAG core 12 and the access key 14. The port protection network 30 is also provided with a FPGA configuration to allow the designer of this port protection network 30 to preconfigure specific security parameters that enables the port protection network to be selectively restrictive. The port protection network 30 is also separate and independent from the access system between the predefined parameters of the at least one JTAG core 12 and the access key 14 in order to provide access into the at least one JTAG core 12. As such, the access system between the predefined parameters of the at least one JTAG core 12 and the access key 14 provides a first level of protection and security, and the port protection network 30 provides a second level of protection and security separate and independent from the access system between the at least one JTAG core 12 and the access key 14.

Still referring to FIGS. 2 and 3, the port protection network 30 includes a configurable agent device or a first-data-in-first-data-out (FIFO) device 32. The agent device 32 includes a first I/O port 32A that operatively connects with at least one output port 16B of the streaming bus 16 via a first side channel 34 (see FIG. 3). In the illustrated embodiment, agent device 32 receives data and/or signals from the streaming bus 16 during operation via the first side channel 34. The agent device 32 also includes a second I/O port 32B that operatively connects with the second I/O port 13B of the TAP 13 via a first security channel 36. In the illustrated embodiment, the agent device 32 may receive information from the TAP 13 and may send and/or output information to the TAP 13 during operation via the first security channel 36; such receiving and outputting information to and from the TAP 13 is described in more detail below.

The agent device 32 of the port protection network 30 is also configured with a configurable protection parameter. This protection parameter enables the selective restriction via the port protection network 30 to provide an additional level of security in conjunction with the access system between the at least one JTAG core 12 and the access key 14. The protection parameter of the agent device 32 restricts further access into the port protection network 30 along with access into the at least one JTAG core 12, the streaming bus 16, and other downstream devices operatively connected with the streaming bus 16 through the at least one JTAG core 12. Such use and operation of this selective restriction by the agent device 32 of the port protection network 30 is described in more detail below.

Still referring to FIGS. 2 and 3, the port protection network 30 also includes a configurable master device or bus master eFPGA 38. The master device 38 includes a first I/O port 38A that operatively connects with at least one input port 16A of the streaming bus 16 via a second side channel 40. The master device 38 also includes a second I/O port 38B that operatively connects with the third I/O port 13C of the TAP 13 via a second security channel 42. In the illustrated embodiment, the master device 38 is configured to receive data from the TAP 13 when the agent device 32 allows access to the master device 38, which is described in more detail below. Additionally, the master device 38 is configured to output data to the streaming bus 16 where such output data may be output to downstream programmable device such as the at least one programmable device 20.

Referring to FIG. 2, the port protection network 30 also includes a protection key 44 that enables access into the port protection network 30. Specifically, the protection key 44 provided herein may be a predefined bit stream that matches the protection parameter of the agent device 32 to enable access into the at least one JTAG core 12 and other downstream devices operatively connected inside of the IC 10 and downstream devices operatively connected with the IC 10. During operation, a user may load the protection key 44 into the at least one JTAG core 12, via the TAP 13, to change the agent master 32 from a locked state to an unlocked state. In the locked state, the agent device 32 restricts access into the master device 38, which ultimately restricts access to the streaming bus 16, the eFPGA 18, and the at least one programmable device 20. As such, the second security channel 42 is inaccessible to the master device 38 when the agent device is provided in the locked state. In the unlocked state, the agent device 32 allows access into the master device 38, which ultimately allows access to the streaming bus 16, the eFPGA 18, and the at least one programmable device 20. As such, the second security channel 42 is accessible to the master device 38 when the agent device is provided in the unlocked state. As stated previously, a user is enabled to access the streaming bus 16, the eFPGA 18, and the at least one programmable device 20 once both the access key 14 and the protection key 44 are loaded into the at the least one JTAG core 12 and the port protection network 30.

The use of the protection key 44 with the agent device 32 is considered advantageous at least because the protection key 44 enables the agent device 32 to open and unlock access into the IC 10 through the at least one JTAG core 12. As such, the matching of the protection key 44 with the configurable protection parameter of the agent device 32 selectively restricts users from performing debugging operations and features with the at least one JTAG core 12. Such debugging operations and features include JTAG boundary testing, full on-chip buss memory mapping, memory built-in self-testing (MBIST), logic built-in self-testing (LBIST), and other various debugging operations of the like. Moreover, the matching of the protection key 44 with the configurable protection parameter of the agent device 32 selectively restricts users from accessing the streaming bus 16 and other devices downstream operatively connected with the IC 10 when the IC 10 is provided in the field.

The port protection network 30 is considered advantageous at least because the port protection network 30 may be provided at different security settings for the IC 10 based on the environment of the IC 10. In one instance, the port protection network 30 may be configured by a designer to allow open and/or free access into the at least one JTAG core 12 in a testing and/or debugging environment when security is not an issue and the environment is not hostile. In another instance, the port protection network 30 may be configured by a designer to restrict and limit the access into the at least one JTAG core 12 when being used in the field and security is a high priority due to the environment being hostile.

Having now described the security components and networks of the IC 10, method of using the IC 10 are provided in more detail below.

Prior to receiving one or both of the access key 14 and the protection key 44, any external user of the IC 10 is unable to access the streaming bus 16, the eFPGA 18, and the at least one programmable device 20 through the at least one JTAG core 12. At this state, the at least one JTAG core 12 is provided in a locked or restricted state to prevent communication between the user and the streaming bus 16, the eFPGA 18, and the at least one programmable device 20. The port protection network is also provided in a locked or restricted state to prevent communication between the user the streaming bus 16, the eFPGA 18, and the at least one programmable device 20. As described above, both the at least one JTAG CORE 12 and the port protection network 30 may be provided in the unlocked or accessible state once both the access key 14 and the protection key 44 are loaded into the at least one JTAG core 12 by an authorized user.

During operation, a user of the IC 10 is able to access the streaming bus 16, the eFPGA 18, and the at least one programmable device 20 via the at the at least one JTAG core 12 by providing the access key 14 of the at least one JTAG core 12 and the protection key 44 of the port protection network 30. As described herein, the access key 14 of the at least one JTAG core 12 is loaded into the at least one JTAG core 12, via the TAP 13, at a first time interval, and the protection key 44 of the port protection network 30 is loaded into the at least one JTAG core 12, via the TAP 13, at a second time interval.

In other exemplary embodiments, a user of an integrated circuit described herein may load a protection key into a port protection network and an access key of at least one JTAG core at various time intervals. In one exemplary embodiment, a user of an integrated circuit described herein may load a protection key into a port protection network and an access key of at least one JTAG core simultaneously. In another exemplary embodiment, a user of an integrated circuit described herein may load a protection key into a port protection network prior to loading an access key of at least one JTAG core.

First, the user loads the access key 14 into the at least one JTAG CORE 12 at the first I/O port 13A of the TAP 13. As stated previously, the access key 14 must match the predefined access parameter of the at least one JTAG CORE 12 in order to change the at least one JTAG CORE 12 from the locked state to the unlocked state. If the matching access key 14 is loaded into the TAP 13, the at least one JTAG core 12 changes from the locked state to the unlocked state. The at least one JTAG CORE 12 will remain in the locked state if the access key 14 fails to match the predefined access parameter of the at least one JTAG core 12.

Second, the user loads the protection key 44 into the at least one JTAG core 12 via the TAP 13. Once inputted into the TAP 13, the TAP 13 is configured to send and output the protection key 44 to the agent device 32 via the first security channel 36. Prior to receiving the protection key 44, the agent device 32 is provided in the locked state to selectively restrict access past the port protection network 30 and into the streaming bus 16. As stated above, the protection key 44 must match the protection parameter (i.e., the bit stream parameter) of the agent device 32 to provide the agent device 32 in the unlocked state. If the protection key 44 inputted by the user matches the protection parameter of the agent device 32, then the agent device 32 changes from the locked position to the unlocked state. The agent device 32 remains in the locked state if the protection key 44 fails to match the configurable protection parameter of the agent device 32.

Once the agent device 32 is provided in the unlocked state, the agent device 32 allows access the master device 38. As such, the agent device 32 communicates this information to the master device 38 to the TAP 13 via the first security channel 36. The TAP 13 then proceeds to output this communication to the master device 38 via the second security channel 42. At this point, the user is able to access the master device 38 over the second security channel 42 once the agent device 32 changes from the locked state to the unlocked state. As such, the second security channel 42 is restricted and prevent access to the master device 38 when the agent device 32 is provided in the locked position.

Once the at least one JTAG core 12 and the agent device 32 is provided in the unlocked position, the user is able to freely access the streaming bus 16, the eFPGA 18, and the at least one programmable device 20 via the master device 38. During operation, the agent device 32 may receive data and/or information from the streaming bus 16.

The configuration of the port protection network 30 with the at least one JTAG core 12 is considered advantageous at least because this configuration requires two forms of accessibility into the at least one JTAG core 12 via the access key 14 and the protection key 44. As such, the user is restricted from accessing any device and/or components downstream of the at least one JTAG core 12 if the user fails to load the access key 14 that matches the predefined access parameter of the at least one JTAG core and the protection key 44 that matches the configurable protection parameter of the agent device 32. Moreover, the access key 14 and the protection key 44 are different from one another in that neither one of the access key 14 and the protection key 44 are interchangeable for changing the state of the JTAG core 12 and the port protection network 30.

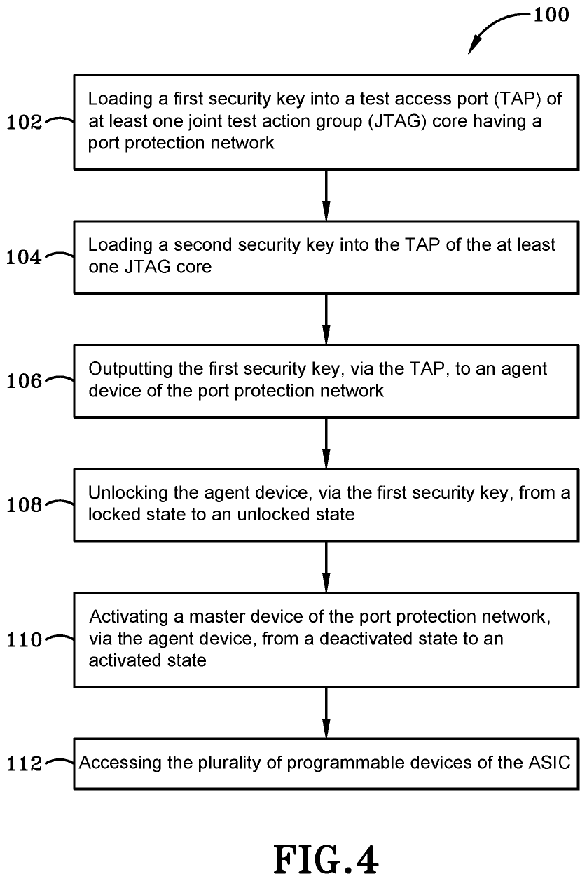

FIG. 4 illustrates a method 100 of accessing a plurality of programmable devices of an application-specific integrated circuit (ASIC). An initial step 102 of method 100 comprises loading a first security key into a test access port (TAP) of at least one joint test action group (JTAG) core having a port protection network. Another step 104 of method 100 comprises loading a second security key into the TAP of the at least one JTAG core. Another step 106 of method 100 comprises outputting the first security key, via the TAP, to an agent device of the port protection network. Another step 108 of method 100 comprises activating the agent device, via the first security key, from a locked state to an unlocked state. Another step 110 of method 100 comprises enabling a master device of the port protection network, via the agent device, from deactivated state to an activated state. Another step 112 of method 100 comprises accessing the plurality of programmable devices of the ASIC.

In other exemplary embodiments, method 100 may include additional and/or optional steps. An optional step comprises outputting data, via a first side channel, from the master device to a streaming bus of the ASIC. An optional step comprises outputting the data, via the streaming bus, to at least one of the plurality programmable devices of the ASIC. An optional step comprises communicating, via a second side channel, between the agent device and the streaming bus. An optional step comprises that the step of outputting the first security key, via the TAP, to the agent device of the port protection network further includes that the first security key is outputted over a first security channel of the port protection network operatively connecting the agent device and the TAP to one another. An optional step comprises that the step of activating a master device of the port protection network, via the agent device, from deactivated state to an activated state further includes that the master device was activated over a second security channel of the port protection network.

As described herein, aspects of the present disclosure may include one or more electrical, pneumatic, hydraulic, or other similar secondary components and/or systems therein. The present disclosure is therefore contemplated and will be understood to include any necessary operational components thereof. For example, electrical components will be understood to include any suitable and necessary wiring, fuses, or the like for normal operation thereof. Similarly, any pneumatic systems provided may include any secondary or peripheral components such as air hoses, compressors, valves, meters, or the like. It will be further understood that any connections between various components not explicitly described herein may be made through any suitable means including mechanical fasteners, or more permanent attachment means, such as welding or the like. Alternatively, where feasible and/or desirable, various components of the present disclosure may be integrally formed as a single unit.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of technology disclosed herein may be implemented using hardware, software, or a combination thereof. When implemented in software, the software code or instructions can be executed on any suitable processor or collection of processors, whether provided in a single computer or distributed among multiple computers. Furthermore, the instructions or software code can be stored in at least one non-transitory computer readable storage medium.

Also, a computer or smartphone utilized to execute the software code or instructions via its processors may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers or smartphones may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes outlined herein may be coded as software/instructions that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, USB flash drives, SD cards, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the disclosure discussed above. The computer readable medium or media can be transportable, such that the program or programs stored thereon can be loaded onto one or more different computers or other processors to implement various aspects of the present disclosure as discussed above.

The terms “program” or “software” or “instructions” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present disclosure need not reside on a single computer or processor, but may be distributed in a modular fashion amongst a number of different computers or processors to implement various aspects of the present disclosure.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

All definitions, as defined and used herein, should be understood to control over dictionary definitions, definitions in documents incorporated by reference, and/or ordinary meanings of the defined terms.

“Logic”, as used herein, includes but is not limited to hardware, firmware, software and/or combinations of each to perform a function(s) or an action(s), and/or to cause a function or action from another logic, method, and/or system. For example, based on a desired application or needs, logic may include a software controlled microprocessor, discrete logic like a processor (e.g., microprocessor), an application specific integrated circuit (ASIC), a programmed logic device, a memory device containing instructions, an electric device having a memory, or the like. Logic may include one or more gates, combinations of gates, or other circuit components. Logic may also be fully embodied as software. Where multiple logics are described, it may be possible to incorporate the multiple logics into one physical logic. Similarly, where a single logic is described, it may be possible to distribute that single logic between multiple physical logics.

Furthermore, the logic(s) presented herein for accomplishing various methods of this system may be directed towards improvements in existing computer-centric or internet-centric technology that may not have previous analog versions. The logic(s) may provide specific functionality directly related to structure that addresses and resolves some problems identified herein. The logic(s) may also provide significantly more advantages to solve these problems by providing an exemplary inventive concept as specific logic structure and concordant functionality of the method and system. Furthermore, the logic(s) may also provide specific computer implemented rules that improve on existing technological processes. The logic(s) provided herein extends beyond merely gathering data, analyzing the information, and displaying the results. Further, portions or all of the present disclosure may rely on underlying equations that are derived from the specific arrangement of the equipment or components as recited herein. Thus, portions of the present disclosure as it relates to the specific arrangement of the components are not directed to abstract ideas. Furthermore, the present disclosure and the appended claims present teachings that involve more than performance of well-understood, routine, and conventional activities previously known to the industry. In some of the method or process of the present disclosure, which may incorporate some aspects of natural phenomenon, the process or method steps are additional features that are new and useful.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. An integrated circuit, comprising:
a streaming bus;
at least one joint test action group (JTAG) core operatively connected with the streaming bus, the at least one JTAG core comprising:
a test access port (TAP) adapted to connect with a JTAG interface, wherein the at least one JTAG core is adapted to access a plurality of programmable devices;
a port protection network; and
a set of preconfigured security parameters;
wherein each of the port protection network and the at least one JTAG interface are configured to selectively restrict access, via the at least one JTAG core, to the plurality of programmable devices.

2. The integrated circuit of claim 1, wherein each of the port protection network and the at least one JTAG interface is configured to selectively restrict access to the plurality of programmable devices through the at least one JTAG core independently and separately from one another.

3. The integrated circuit of claim 1, wherein the port protection network comprises:
an agent device operatively connected with the streaming bus and the TAP;
wherein the agent device is operative to communicate with one or both of the streaming bus and the TAP.

4. The integrated circuit of claim 3, wherein the port protection network further comprises:
a master device operatively connected with the streaming bus and the TAP;
wherein the master device is operative to communicate with one or all of the agent device, the TAP, and the streaming bus.

5. The integrated circuit of claim 4, wherein the set of preconfigured security parameters further comprises:
a first protection parameter provided with the agent device of the port protection network that maintains the agent device in a locked state; and
a second protection parameter provided with the at least one JTAG core that maintains the at least one JTAG core in a locked state.

6. The integrated circuit of claim 5, further comprising:
a first security channel of the port protection network operatively connecting the agent device and the TAP with one another;
wherein the agent device of the port protection network, in response to receiving a first security key matching the first protection parameter, is in an unlocked state once the first security key is loaded into the TAP of the at least one JTAG and output to the agent device via the first security channel.

7. The integrated circuit of claim 6, wherein the port protection network further comprises:
a second security channel operatively connecting the master device and the TAP with one another;
wherein the agent device and the master device communicate with one another via the first security channel and the second security channel; and
wherein the master device is accessible subsequent to the agent device of the port protection network being provided in the unlocked state.

8. The integrated circuit of claim 7, wherein the at least one JTAG core, in response to receiving a second security key matching the second protection parameter, is in an unlocked state once the second security key is loaded into the TAP of the at least one JTAG core.

9. The integrated circuit of claim 8, wherein the port protection network further comprises:
a first side channel operatively connecting the agent device and the streaming bus with one another;
wherein the streaming bus outputs data to the agent device via the first side channel.

10. The integrated circuit of claim 9, wherein the port protection network further comprises:
a second side channel operatively connects the master device and the streaming bus with one another;
wherein the master device outputs data to the streaming device via the second side channel.

11. A port protection network provided with a joint test action group (JTAG) core, comprising:
an agent device operatively connected with a streaming bus and a test access port (TAP) of the JTAG core;
a master device operatively connected with the streaming bus and the TAP of the JTAG core;
wherein the agent device is configured to selectively restrict access to the master device through the JTAG core.

12. The port protection network of claim 11, further comprising:
a set of preconfigured security parameters provided with the port protection network and the JTAG core, the set of preconfigured security parameters comprising:
a first protection parameter provided with the agent device of the port protection network that maintains the agent device in a locked state; and
a second protection parameter provided with the at least one JTAG core that maintains the at least one JTAG core in a locked state.

13. The port protection network of claim 12, further comprising:
a first security channel of the port protection network operatively connecting the agent device and the TAP with one another;
wherein the agent device, in response to receiving a first security key matching the first protection parameter, is in an unlocked state once the first security key is loaded into the TAP of the JTAG core and output to the agent device via the first security channel.

14. The port protection network of claim 13, wherein the port protection network further comprises:
a second security channel operatively connecting the master device and the TAP with one another;
wherein the agent device and the master device communicate with one another via the first security channel and the second security channel; and
wherein the master device is accessible once the agent device is unlocked.

15. The port protection network of claim 14, wherein the JTAG core, in response to receiving a second security key matching the second protection parameter, is in an unlocked state once the second security key is loaded into the TAP of the JTAG core.

16. A method of accessing a plurality of programmable devices of an application-specific integrated circuit (ASIC), comprising steps of:
loading a first security key into a test access port (TAP) of at least one joint test action group (JTAG) core having a port protection network;
loading a second security key into the TAP of the at least one JTAG core;
outputting the first security key, via the TAP, to an agent device of the port protection network;
unlocking the agent device, via the first security key, from a locked state to an unlocked state;
activating a master device of the port protection network, via the agent device, from a deactivated state to an activated state; and
accessing the plurality of programmable devices of the ASIC.

17. The method of claim 16, further comprising:
outputting data, via a first side channel, from the master device to a streaming bus of the ASIC.

18. The method of claim 17, further comprising:
outputting the data, via the streaming bus, to at least one of the plurality programmable devices of the ASIC.

19. The method of claim 18, further comprising:
communicating, via a second side channel, between the agent device and the streaming bus.

20. The method of claim 16, wherein the step of outputting the first security key, via the TAP, to the agent device of the port protection network further includes that the first security key is outputted over a first security channel of the port protection network operatively connecting the agent device and the TAP to one another.
